(19) United States
(12) Patent Application Publication
(10) Pub. No.: US 2020/0278904 A1
(43) Pub. Date: Sep. 3, 2020

(54) Retry-Read Method

(71) Applicants: Goke Taiwan Research Laboratory Ltd., Taipei City 114 (TW); Xinsheng Intelligent Technology Co., Ltd., Jiangsu (CN)

(72) Inventors: Po-Chien Chang, Taipei City (TW); Guo-He Huang, Taipei City (TW)

(21) Appl. No.: 16/289,723

(22) Filed: Mar. 1, 2019

(51) Int. Cl. G06F 11/10; G11C 16/34; G11C 29/52

(52) U.S. Cl. CPC G06F 11/1048; G11C 29/52; G11C 16/349; G06F 11/1068

(57) ABSTRACT

A retry-read method includes the steps of collecting sets of environmental data, deriving sets of parameters from the sets of environmental data, deriving a preferred set of parameters from the sets of parameters, reading data by executing a round of retry-read based on the preferred set of parameters, and determining whether an error-correcting code of the data is correct. Weights of the parameters in the preferred set are adjusted and the process returns to the step of deriving the preferred set of parameters if the error-correcting code is not correct. The process ends if the error-correcting code is correct.

### BACKGROUND OF INVENTION

### 1. Field of Invention

The present invention relates to a retry-read method and, more particularly, to a retry-read method that determines parameters in an adaptive manner.

### 2. Related Prior Art

A NAND flash memory stores data. However, after the data is stored in the NAND flash memory, threshold the voltage begins to drift as time elapses. The data might be uncorrectable when the threshold voltage drifts to a certain extent. That is, error bits occur. The possible number of such error bits gets larger as the capacity of the NAND flash memory gets larger. Moreover, for any NAND flash memory, the possible number of such error bits gets larger as the program/erase count gets larger or the temperature gets higher.

Referring to FIG. 2, there is shown a conventional retry-read method. In the beginning, data is read in an ordinary manner. Then, it is determined whether an error-correcting code of the data is correct. The process ends if so, and a first round of retry-read is executed according to a first set of parameters if otherwise. Then, it is determined whether the error-correcting code of the data is correct. The process ends if so, and a second round of retry-read is executed according to a second set of parameters if otherwise. This process is repeated until the error-correcting code is correct in an N^{th} round of retry-read. As more rounds of retry-read are executed, latency gets longer, i.e., performance gets lower. Hence, it takes a lot of time to execute the conventional retry-read method to effectively read data, i.e., the efficiency is low.

The present invention is therefore intended to obviate or at least alleviate the problems encountered in prior art.

### SUMMARY OF INVENTION

It is the primary objective of the present invention to provide a data storage device with a retry method.

To achieve the foregoing objective, the retry-read method includes the steps of collecting sets of environmental data, deriving sets of parameters from the sets of environmental data, deriving a preferred set of parameters from the sets of parameters, reading data by executing a round of retry-read based on the preferred set of parameters, and determining whether an error-correcting code of the data is correct. Weights of the parameters in the preferred set are adjusted and the process returns to the step of deriving the preferred set of parameters if the error-correcting code is not correct. The process ends if the error-correcting code is correct.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a flow chart of a retry-read method according to the preferred embodiment of the present invention; and

FIG. 2 is a flow chart of a conventional retry-read method.

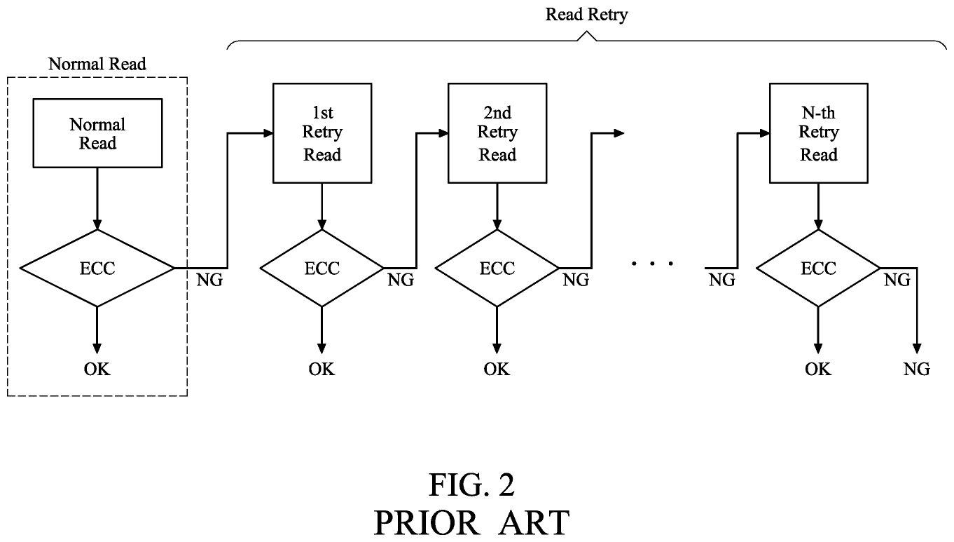

### DETAILED DESCRIPTION OF PREFERRED EMBODIMENT

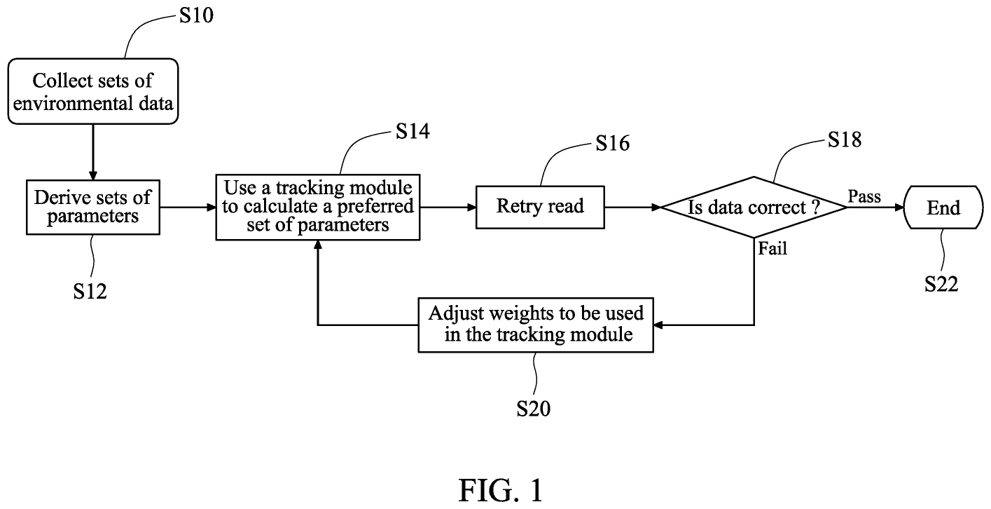

Referring to FIG. 1, there is shown a retry-read method for a data storage device according to the preferred embodiment of the present invention. Samples are obtained from a batch of NAND flash memories before the batch of NAND flash memories is delivered to users from a manufacturer. The retry-read method is executed on the samples for a plurality of times. Thus, a set of parameters is obtained. The users execute the retry-read method based on this set of parameters to effectively and efficiently read data after the batch of NAND flash memories is delivered to the users from the manufacturer.

At S10, sets of environmental data are collected. Each set of environmental data includes but not limited to a word line layer, a program/erase count, a temperature of writing, a temperature of reading and a mode. The mode includes but not limited to ‘read disturb’, ‘data retention’ and ‘open block.’

Then, at S12, sets of parameters are derived from the sets of environmental data. Each set of parameters corresponds to one set of environmental data.

Then, at S14, a preferred set of parameters is derived from the sets of parameters. Preferably, an artificial intelligence module is used to derive the preferred set of parameters from the sets of parameters based on weights.

Then, at S16, data is read via executing a round of retry-read based on the preferred set of parameters.

Then, at S18, it is determined whether an error-correcting code of the data is correct.

The process goes to S20 if the error-correcting code is not correct. At S20, weights for the parameters in the preferred set are adjusted. The weights are to be used in the tracking module. Then, the process returns to S14 to provide another preferred set of parameters.

The process goes to S22 if the error-correcting code is correct. At S22, the process ends.

In the method of the present invention, an optimal set of weights will finally be obtained for the NAND flash memory. In practice, the optimal set of weights for the NAND flash memory can be used for other NAND flash memories in a same batch. That is, an optimal set of weights represents properties of a batch of NAND flash memories. Hence, it is likely that different sets of weights are used for different batches of NAND flash memories.

As discussed above, the manufacturer executes the retry-read method before the batch of NAND flash memories is delivered to the users. The manufacturer executes only the steps represented by S10 to S22.

As discussed above, a user executes the retry-read method to effectively and efficiently read data after the batch of NAND flash memories is delivered to the users. The user executes only the steps represented by S14 to S22.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A retry-read method comprising the steps of:
collecting sets of environmental data (S10) of a data storage device;
deriving sets of parameters from the sets of environmental data (S12);
deriving a preferred set of parameters from the sets of parameters (S14);
reading data by executing a round of retry-read based on the preferred set of parameters (S16);
determining whether an error-correcting code of the data is correct (S18);
adjusting weights of the parameters in the preferred set and returning the step of deriving the preferred set of parameters if the error-correcting code is not correct (S20); and ending if the error-correcting code is correct (S22);
wherein an optimal set of weights will finally be obtained for the data storage device, and the optimal set of weights for the NAND flash memory can be used for other NAND flash memories in a same batch.

2. The retry-read method according to claim 1, wherein the set of environmental data comprises a word line, a program/erase count, temperature of writing, temperature of reading and a mode.

3. The retry-read method according to claim 2, wherein the mode comprises ‘read interrupt’, ‘data retention’ and ‘open block.’

4. The retry-read method according to claim 1, wherein the step of deriving the preferred set of parameters comprising the step of using an artificial intelligence module to calculate the preferred set of parameters.
